(19) United States
(12) Patent Application Publication
(10) Pub. No.: US 2026/0150284 A1
(43) Pub. Date: May 28, 2026

(54) METHOD FOR MANUFACTURING AN INTEGRATED CIRCUIT COMPRISING AT LEAST ONE SELECTION TRANSISTOR WITH A VERTICAL GATE OF A NON-VOLATILE MEMORY CELL AND AT LEAST ONE DEEP TRENCH CAPACITOR

(71) Applicant: STMicroelectronics International N.V., Geneva (CH)

(72) Inventors: Carlos Augusto SUAREZ SEGOVIA, Seyssinet-Pariset (FR); Linda PARMIGIANI, Domene (FR)

(73) Assignee: STMicroelectronics International N.V., Geneva (CH)

(21) Appl. No.: 19/398,855

(22) Filed: Nov. 24, 2025

(30) Foreign Application Priority Data
Nov. 25, 2024 (FR) FR2412890

(51) Int. Cl. H10B 41/35; H01L 21/265; H01L 21/28; H01L 21/308; H10D 1/00; H10D 1/66

(52) U.S. Cl. CPC H10B 41/35; H10D 1/047; H10D 1/665; H10D 64/01302; H10P 30/204; H10P 30/21; H10P 50/691

(57) ABSTRACT

A semiconductor substrate includes a first trench and a second trench. The first trench forms at least one element of a first electronic component, where the first electronic component extends from the surface of the substrate to a first depth. The second trench forms at least one element of a second electronic component different from the first electronic component. The second electronic component extends from the surface of the substrate to a second depth. A ratio between the first depth and the second depth is greater than or equal to 1.1.

### PRIORITY CLAIM

This application claims the priority benefit of French Application for Patent No. FR2412890, filed on Nov. 25, 2024, the content of which is hereby incorporated by reference in its entirety to the maximum extent allowable by law.

### TECHNICAL FIELD

The present description relates to semiconductor substrates and a method for forming deep trenches in a semiconductor substrate.

The description relates in particular to the fabrication of an integrated circuit comprising at least one selection transistor with a vertical gate of a non-volatile memory cell and at least one deep trench capacitor. It applies in particular to the co-integration of non-volatile memory cells and high-density deep trench capacitors.

### BACKGROUND

Deep trench structures are widely used because of the density and improved performance that they offer when they are used in semiconductor devices.

A phase of forming deep trenches in the semiconductor substrate of an integrated circuit can also be used for manufacturing the vertical gates of buried vertical gate transistors, or for manufacturing vertical capacitive elements in the semiconductor substrate.

In a known example of manufacturing deep trench structures for the vertical gates of transistors and for the vertical capacitive elements, two distinct methods are generally used (one for the gates and another for the capacitors) because of the different optimum depths for the vertical gates of transistors and for the vertical capacitive elements. This method also leads to longer semiconductor assembly manufacturing time and higher costs for the two dissociated methods.

Consequently, conventional techniques propose a common method for manufacturing deep trench structures for the vertical gates of transistors and for the vertical capacitive elements, but this common method produces trenches having the same depth for said vertical components. This depth is generally chosen to meet the optimum performance requirements of either vertical gates of transistors or vertical capacitive elements. For example, deep trenches with an example depth of 600 nm to 1,200 nm are etched to then comprise the vertical gates of transistors and the vertical capacitive elements. However, the same depth of the deep trench cannot be optimal for both electronic components.

Indeed, the depth of the trenches accommodating vertical gates influences the performance of the buried transistors, this established depth can therefore be very difficult to modify. For example, buried vertical gate transistors are used in memory cells of non-volatile memories.

However, it is advantageous for the vertical capacitive elements to benefit from deeper trenches, in order to increase the surface capacitive value of said capacitive elements. In other words, it would be desirable to manufacture deeper trenches for the electrodes of vertical capacitive elements than the trenches for the buried vertical gate transistors, at a lower cost. The deep trenches may be coated with an electrically insulating material on the side surfaces thereof, then filled with an electrically conductive material.

There is therefore a need to propose a unique method for forming trenches having different and optimal depths, for each of the different electronic components.

There is also a need for a method for manufacturing an integrated circuit comprising at least one selection transistor with a vertical gate of a non-volatile memory cell, and preferably several selection transistors with vertical gates, and at least one deep trench capacitor, and preferably several deep trench capacitors.

### SUMMARY

In an embodiment, a method for etching a semiconductor substrate or for manufacturing an integrated circuit comprises: forming a first mask resistant to a first etching on a surface of an assembly comprising at least one wafer of the semiconductor substrate, the first mask comprising at least one opening, said at least one opening placed facing a location of at least one first deep trench to be formed in said substrate and said first mask forming an obstruction facing a location of at least one second deep trench to be formed in said substrate; first etching said assembly to partially form said at least one first trench; at least partially removing the first mask and forming, on said surface of said assembly, a second mask resistant to a second etching, the second mask comprising a plurality of openings, at least one first opening of the plurality of openings is placed facing the partially formed first trench and at least one second opening of the plurality of openings is placed facing the location of the at least one second deep trench to be formed; and second etching said assembly to form said at least one first deep trench and said at least one second deep trench.

It is thus possible to obtain a vertical gate of a selection transistor of a non-volatile memory cell and a portion of a deep trench capacitor.

According to one implementation, the method further comprises the following successive steps: ion implantation, in the semiconductor substrate, at the bottom of said first and second deep trenches, forming a first implanted region and a second implanted region; depositing a dielectric layer on the sidewalls and on the bottom of said deep trenches; and depositing a conductive material filling said deep trenches.

According to one implementation, the method further comprises the step of filling the first trench partially formed with a planarizing material, wherein the planarizing material is amorphous carbon or a spin-on carbon composition.

According to another implementation, the method further comprises the step of removing at least one portion of the second mask from the surface of the assembly, before the second etching step, and depositing a dielectric material and a conductive material in the first and the second formed trenches.

Preferably, the conductive material is a doped polysilicon.

According to one embodiment, the assembly further comprises at least one of the following elements: a protective layer such as an oxide layer; a second mask such as a silicon containing anti-reflective coating layer; an anti-reflective coating such as a dielectric anti-reflective coating layer; a hard mask layer such as an amorphous carbon layer; and a dielectric layer such as a silicon nitrite layer.

According to another aspect, an assembly comprises an integrated circuit manufactured according to the described method.

According to another aspect, a method is provided for manufacturing an integrated circuit comprising at least one selection transistor with a vertical gate of a non-volatile memory cell, and at least one deep trench capacitor. The manufacturing method comprises the following steps: forming a stack comprising, on a semiconductor substrate, a hard mask layer and a first mask covering the hard mask layer, the first mask being resistant to a first main etching, having an opening located in a first zone facing a first deep trench to be formed on the one hand, and forming an obstruction in a second zone facing a second deep trench to be formed on the other hand; preliminary localized etching, through the opening of the first mask, so that the opening extends through the hard mask layer; removing the first mask; first main etching, through the opening, thereby forming a partial trench in the semiconductor substrate; depositing a filling material that fills the partial trench; forming a second mask on the hard mask layer, the second mask being resistant to a second main etching, having a first opening located in the first zone facing the partial trench on the one hand, and a second opening in the second zone facing the second deep trench to be formed on the other hand; intermediate localized etching, through the first opening of the second mask, so that it extends through the hard mask layer and removes the filling material from the partial trench, and through the second opening of the second mask so that it extends through the hard mask layer; second main etching, through the first opening thereby forming the first deep trench in the semiconductor substrate, and through the second opening thereby forming the second deep trench in the substrate.

The manufacturing method may comprise, after the second main etching step, an ion implantation step in the semiconductor substrate, through the first and second openings of the hard mask layer, thereby forming a first doped region (implanted region) extending from a bottom surface of the first deep trench, and a second doped region (implanted region) extending from a bottom surface of the second deep trench.

The manufacturing method may comprise, after the ion implantation step, a step of forming an electrically insulating layer covering the sidewalls and a bottom surface of the deep trenches.

The manufacturing method may comprise, after the step of forming the electrically insulating layer, a step of forming an electrically conductive material, for example polysilicon, filling the deep trenches.

One of the deep trenches thus formed, together with the insulating layer and the conductive material, may form a vertical gate of a selection transistor of a non-volatile memory cell. The doped (implanted) region may form a source region (also referred to as a source implant) of the selection transistor.

The other of the deep trenches thus formed, together with the insulating layer and the conductive material, may form a portion of a deep trench capacitor.

The manufacturing method may comprise, after the step of forming the electrically conductive material, steps of fabricating the selection transistor of the non-volatile memory cell and steps of fabricating the deep trench capacitor.

A first set of deep trench capacitors may be fabricated simultaneously, the deep trenches of the first set having a same depth that is different from the depth of the deep trench forming the vertical gate of the selection transistor.

A second set of deep trench capacitors may be fabricated simultaneously, the deep trenches of the second set having a same depth that is different from the depth of the deep trenches of the first set.

According to another aspect, an assembly comprises: at least one semiconductor substrate, the substrate comprising at least one first trench and at least one second trench disposed within the substrate. The first trench comprises at least one element of a first electronic component that extends from the surface of the assembly according to a first depth. The second trench comprises at least one element of a second electronic component different from the first electronic component. The second electronic component extends from the surface of the assembly with a second depth.

According to another aspect, an integrated circuit assembly is provided, comprising: at least one semiconductor substrate, the substrate comprising at least one first deep trench and at least one second deep trench arranged within the substrate and having different depths; the first and second deep trenches each comprising an electrically insulating layer covering the sidewalls and the bottom of the deep trenches, and an electrically conductive material filling said deep trenches; a first implanted region extending into the semiconductor substrate from the bottom of the first trench, and a second implanted region extending into the semiconductor substrate from the bottom of the second trench; the first deep trench forming part of an element of a first electronic component, and the second deep trench forming part of an element of a second electronic component different from the first electronic component, the elements of the first and second components being selected from a vertical gate of a selection transistor of a non-volatile memory cell and a portion of a deep trench capacitor.

The first and second deep trenches respectively have a first and a second depth, wherein the ratio between the first depth and the second depth is eleven-tenth or more, for example between 1.1 and 2.

In one embodiment, the element of the first electronic component is a selection transistor element of a non-volatile memory cell of the embedded Select in Trench Memory (eSTM) type and the element of the second electronic component is an element of a deep trench capacitor.

In one embodiment, the first depth is between 330 and 1,200 nm, and the second depth is between 300 and 600 nm.

The integrated circuit may comprise a first set of deep trench capacitors whose deep trenches have a same depth that is different from the depth of the deep trench forming the vertical gate of the selection transistor.

The integrated circuit may comprise a second set of deep trench capacitors whose deep trenches have a same depth that is different from the depth of the deep trenches of the first set.

### BRIEF DESCRIPTION OF THE DRAWINGS

Other advantages and features of the invention will appear upon examining the detailed description of non-limiting embodiments and implementations, and from the appended drawings, wherein:

FIGS. 1A to 1I shows steps in a method of manufacturing;

FIG. 2 shows the result of a step of filling at least one trench with planarizing material;

FIG. 3 shows a top view of the substrate after forming the deep trenches;

FIG. 4A is a schematic and partial cross-sectional view of non-volatile memory cells comprising at least one selection transistor with a vertical gate; and

FIG. 4B is a schematic and partial cross-sectional view of high-density deep trench capacitors.

### DETAILED DESCRIPTION

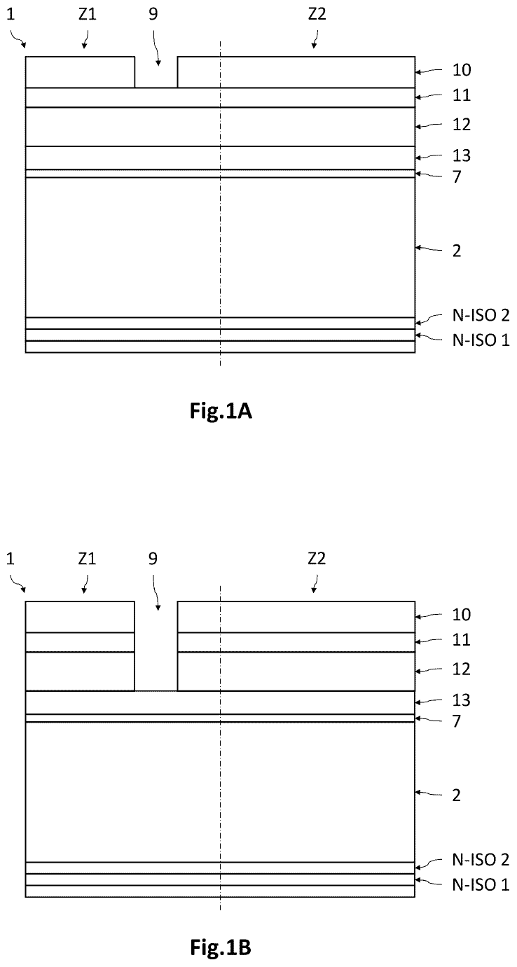

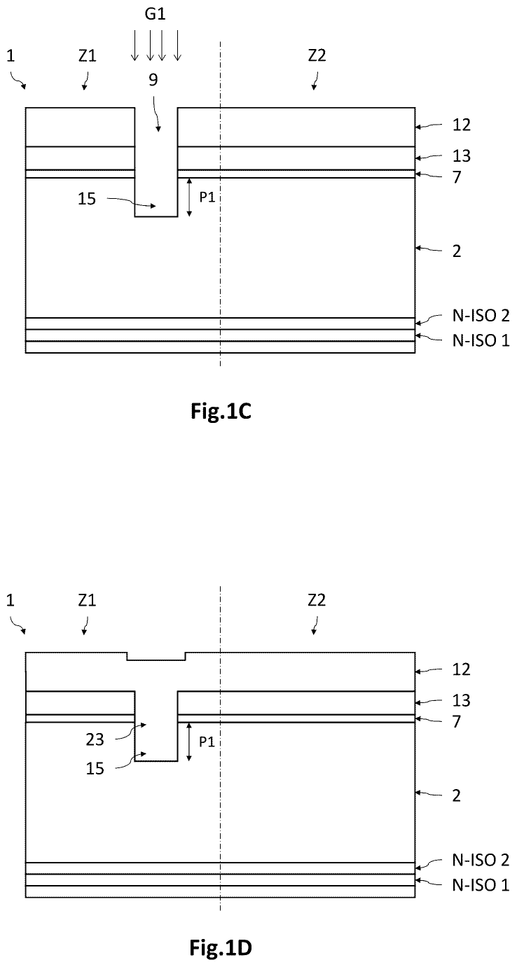

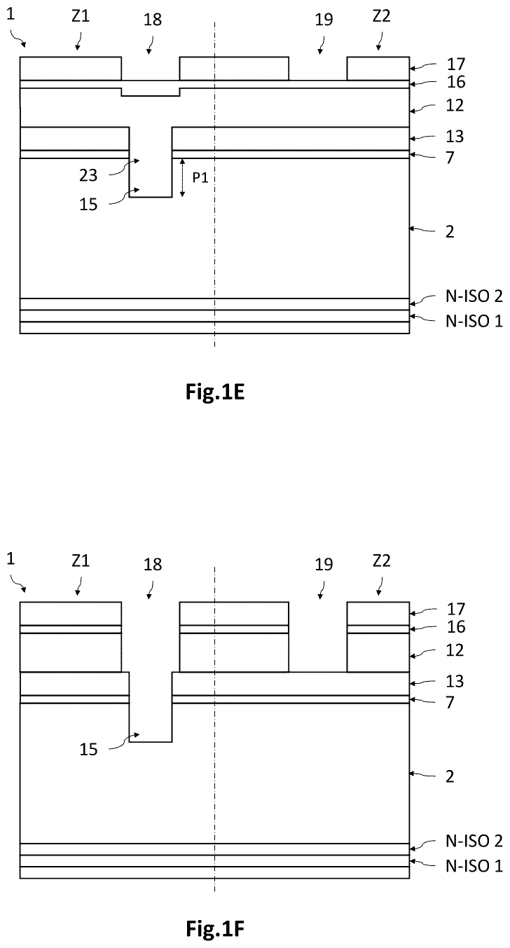

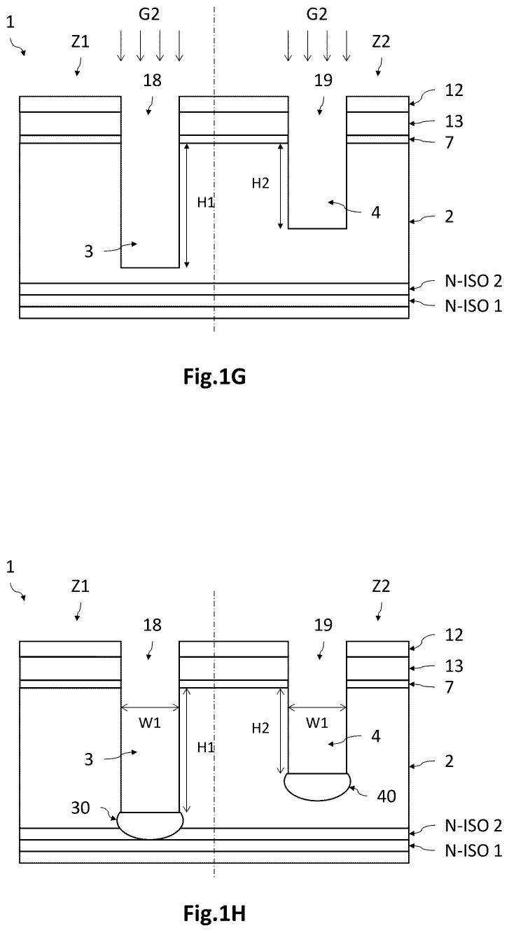

Reference is now made to FIGS. 1A to 1I which shows steps in a method of deep trench manufacturing.

FIG. 1A illustrates an assembly 1 comprising a semiconductor substrate 2 wafer.

The method may relate to the fabrication of an integrated circuit comprising at least one selection transistor (access transistor or buried transistor) with a vertical gate of a non-volatile memory cell and at least one deep trench capacitor.

The integrated circuit preferably comprises several selection transistors with vertical gates and high-density deep trench capacitors. For the sake of clarity, only one deep trench of a selection transistor and one deep trench of a capacitor are shown here.

In this example, the assembly 1 comprises a stack formed, at a minimum, of the following elements arranged successively from bottom to top: the semiconductor substrate 2; a hard mask layer 12; and then a first mask 10.

In this example, the assembly 1 further comprises, positioned between the semiconductor substrate 2 and the hard mask layer 12: a buffer layer 7 and then a dielectric layer 13. The assembly 1 may also comprise a protective layer 11 located between the hard mask layer 12 and the first mask 10.

The semiconductor substrate 2 is, for example, formed of silicon and comprises a first zone Z1 and a second zone Z2.

According to one embodiment, the first zone Z1 may be intended to include a vertical structure capacitive element in the substrate 2 and the second zone Z2 may be intended to include a non-volatile memory region, for example both incorporated into an integrated circuit, or a system on chip such as a microcontroller.

By way of example, the first zone Z1 may be intended for forming a vertical gate of a non-volatile memory cell, and the second zone Z2 may be intended for forming a deep trench capacitor.

The substrate 2 includes a front face, which corresponds to the face of the substrate 2 from which electronic components will be made. The front face may have been covered with a conventional buffer oxide layer 7. For example, the buffer oxide layer 7 includes silicon dioxide obtained by deposition or growth.

A dielectric layer 13, for example a layer of nitrite or of silicon nitride, may be deposited on the buffer oxide layer 7. The dielectric layer 13 may have a thickness, for example, between 60 and 100 nm. The dielectric layer 13 can serve as a hard mask during etching of the substrate 2.

A hard mask layer 12, such as an amorphous carbon layer (α-C, [alpha]-C or a-C) may be deposited on the dielectric layer 13. The amorphous carbon can be obtained in the form of an Advanced Patterning Film (APF). The hard mask layer 12 has a thickness, for example, between 380 and 460 nm, for example 420 nm.

A protective layer 11 may be formed on the hard mask layer 12 and comprise a silicon oxide thickness between 20 and 50 nm, for example 35 nm.

A first photosensitive resin mask 10 is formed on the protective layer 11. The thickness of the first mask 10 is, for example, between 50 and 150 nanometers, for example 100 nm. The first photosensitive mask 10 can be deposited, modeled and removed using conventional lithography techniques.

A layer 10, forming a first mask, for example made of a photosensitive resin, covers the protective layer 11. It has an opening 9 located only in zone Z1, facing a deep trench 3 to be formed. In contrast, in zone Z2, facing a deep trench 4 to be formed, the mask 10 is continuous.

The layers of this stack cover the semiconductor substrate 2 both in zone Z1 and in zone Z2.

In this example, the semiconductor substrate 2 comprises a doped region NISO-1 covered by a doped region NISO-2.

The NISO regions may serve as a conduction (source) function for the selection transistors of the non-volatile memory cells, forming a common “source plane”.

FIG. 1B shows the result of a step of etching (preliminary etching) a pattern in the hard mask layer 12 (and through the protective layer 11), in an opening 9 of the first photosensitive resin mask 10, located in the first zone Z1 and aligned with a location in zone Z1 of the substrate where a trench is intended to be formed.

The step of etching the pattern of the hard mask 12 forms an opening 9 in the hard mask 12 selectively in order to etch the protective layer 11 and the hard mask layer 12, and also in order not to react with the dielectric layer 13. Such selective etching is, for example, implemented by a so-called “dry” or “drying” etching.

In other words, the first mask 10 has an opening 9, and the dry etching step through the opening 9 causes the localized etching of the underlying layers 11 and 12, with the etching stopping here on the dielectric layer 13.

FIG. 1C shows the result of a first etching G1 (referred to also herein as a first main etching). At this step, the first mask 10 and layer 11 have been removed in a conventional manner.

The first etching G1, for example of the “drying” type, for example by Reactive Ion Etching (RIE), is capable of etching the dielectric layer 13, the buffer oxide layer 7 and the silicon of the substrate 2, with a much greater dynamic, selectively, than in the hard mask layer 12.

The first etching G1 is applied to the structure described above in relation to FIG. 1B so as to form at least one partial trench 15 in the opening 9 of the hard mask 12, in the first zone Z1 of the substrate 2.

Said at least one partial trench 15 is etched in the substrate 2 to a depth P1, with respect to the front face of the substrate 2.

In other words, during the main etching G1 through the opening 9 of the hard mask layer 12, the dielectric layer 13 and the buffer layer 7 are locally etched and the opening 9 becomes a through-opening. The main etching G1 causes a partial etching of the substrate 2, facing the opening 9, thereby forming the partial trench 15 to a depth P1 from the upper surface of the substrate 2.

FIG. 1D shows the result of a step of filling at least one partial trench 15 with a planarizing material 23. For example, in the first embodiment, the planarizing material 23 may be a dielectric, for example amorphous carbon.

In one embodiment, the planarizing material 23 fills the partial trench 15 until it reaches and exceeds the level of the surface of the hard mask layer 12. In another example of embodiment, the planarizing material 23 does not completely fill the partial trench 15 and does not reach the upper surface of the hard mask layer 12.

In this first embodiment, the planarizing material 23 is the same material as that of the hard mask layer 12.

In a second embodiment, the planarizing material 23 is not the same material as that of the hard mask layer 12.

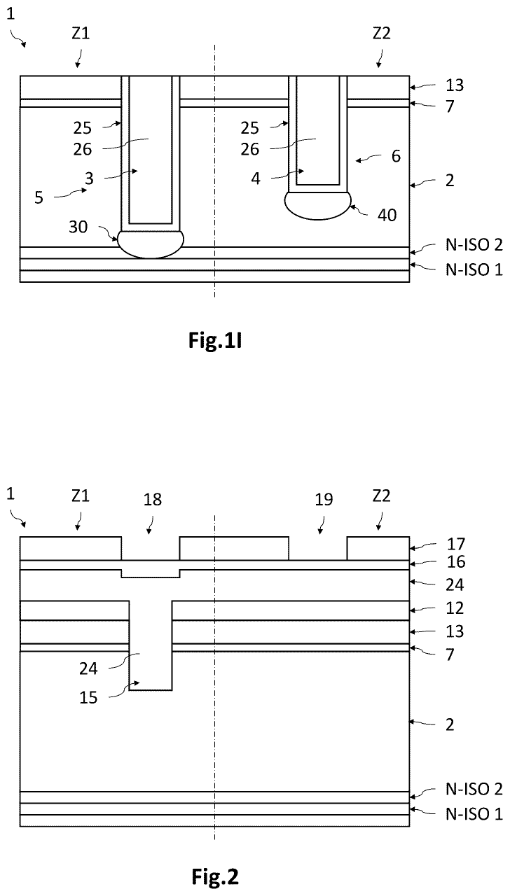

In this regard, reference is made to FIG. 2. FIG. 2 shows the result of a step of filling at least one partial trench 15 with the planarizing material 24 according to the second embodiment. For example, in the second embodiment, the planarizing material 24 may be a Spin-on-Carbon (SOC) material. In this embodiment, the planarizing material 24 can also be deposited on the hard mask layer 12 present on the dielectric layer 13.

In the second embodiment, the planarizing material 24 fills the partial trench 15 and can also be deposited on the hard mask layer 12, thus forming a layer with a flat face.

An anti-reflective coating 16 can be deposited on the hard mask layer 12 and on the planarization material 23 (FIG. 1E); or on the planarization material layer 24 (FIG. 2). It covers the underlying stack and has a flat upper surface. The anti-reflective coating 16 may be, for example, a Dielectric Anti-Reflective Coating (DARC) mask structure or a Silicon containing Anti-Reflective Coating (SiARC) material.

Reference is now made to FIG. 1E relating to the first embodiment described in relation to FIG. 1D. However, the steps described below in relation to FIGS. 1E to 1I apply by analogy to the second embodiment described in relation to FIG. 2.

FIG. 1E shows the result of a step of depositing a second mask 17 on the anti-reflective coating 16. In another embodiment, in the absence of the anti-reflective coating 16, the second mask 17 is deposited directly on the hard mask layer 12 and on the planarization material 23 (FIG. 1E); or on the planarization material layer 24 (FIG. 2). The second mask 17 is a photosensitive resin layer which, in one embodiment, is resistant to a second etching G2 (see FIG. 1G).

The second resin mask 17 comprises a first opening 18 in the first zone Z1 (aligned with the location of the trench 15) and a second opening 19 in the second zone Z2 aligned with a location in zone Z21 of the substrate where a trench is intended to be formed.

The first opening 18 is aligned with said at least one partial trench 15 formed by the first etching G1 (as described above in relation to FIG. 1C) and which is filled with the material by the planarizing material 23, 24 (as described above in relation to FIG. 1D or FIG. 2).

The first opening 18 and the second opening 19 are placed so as to define the locations of a first deep trench 3 and of a second deep trench 4 to be formed respectively during the second etching G2 (see FIG. 1G). The second opening 18 has a width being substantially equal to a width of the opening 9 formed previously. In another embodiment, the width of the first opening 18 is greater than the width of the opening 9 by about 5 to 10%, which makes it possible to better control the depth of the trenches to be formed as well as the width of these trenches.

FIG. 1F shows the result of a step of etching (referred to herein also as an intermediate etching) a pattern in the hard mask layer 12 (and through the anti-reflective coating 16) in the first opening 18 in the first zone Z1 and in the second opening 19 in the second zone Z2 of the second mask 17. Thus, in the first zone Z1, at least one portion of the planarizing material 23, 24 is removed from the partial trench 15. In the second zone Z2, the step of etching the pattern of the hard mask 12 is defined by the second opening 19 selectively in order to etch the anti-reflective coating 16 and the hard mask layer 12, and also in order to react little or not at all with the dielectric layer 13.

Consequently, after the step of etching the pattern in the hard mask layer 12, the assembly 1 comprises a first opening 18 in the hard mask 12 (and the anti-reflective coating 16) facing the partial trench 15 in the substrate 2, and a second opening 19 in the hard mask layer 12 (and in the anti-reflective coating 16). The partial trench 15 has a non-zero depth P1 in the substrate 2, which then makes it possible to form the deep trenches 3, 4 in the substrate 2 with different depths during the same etching step G2 (see FIG. 1G).

FIG. 1G shows the result of a second etching G2 (referred to herein also as a second main etching) in the substrate 2. The second etching G2 is capable of etching the silicon in order to extend the partial trench 15 in the first opening 18 of the hard mask 12. The second etching G2 is also capable of etching the buffer oxide layer 7, the dielectric layer 13 and the silicon of the substrate 2 in the second opening 19 of the hard mask 12.

In this regard, the second etching G2, for example of the “drying” type, for example by reactive ion etching, is configured to etch the dielectric layer 13, the buffer oxide layer 7 and the silicon of the substrate 2, with a selectively much greater dynamic than in the hard mask layer 12.

Following the step of the second etching G2, at least one portion of the hard mask 12 can also be etched, so that the thickness remaining after the second etching G2 is less than the initial thickness of the hard mask 12. In one embodiment, before the step of the second etching G2, the second mask 17 has been removed in a conventional manner.

Thus, the first deep trench 3 in the first opening 18 and the second deep trench 4 in the second opening 19 are formed. The deep first trench 3 has a first depth H1 greater than the depth P1 of the partial trench 15 formed previously. The first depth H1 may be between 330 and 1,200 nm for example, and the second deep trench 4 has a second depth H2 between 300 and 600 nm for example. Preferably, the ratio “H1/H2” between the first depth H1 and the second depth H2 is eleven-tenth or more, for example between 1.1 and 2.

The first deep trench 3 comprises a width W1, for example, between 30 and 50 nm. The width W1 of the first deep trench is substantially equal to or greater than a width of the second deep trench 4. The width of the deep trenches 3, 4 is measured at half the respective depths H1, H2 in the substrate 2.

FIG. 1H shows the result of an implantation of a dopant in the bottom of the deep trenches 3, 4. The implanted dopant may be of the N type if the substrate 2 is of the P type or the implanted dopant may be of the P type if the substrate is of the N type.

Thus, an implanted region 30 (doped region) is obtained, extending into the substrate 2 from the bottom surface of the deep trench 3. This implanted region 30 may be in contact with the underlying NISO-2 region.

A second implanted region 40 (doped region) is also obtained, extending into the substrate 2 from the bottom surface of the deep trench 4. This implanted region 40 may be spaced apart from the underlying NISO-2 region.

The implanted regions 30 and 40 may be formed simultaneously during the same ion implantation step.

The hard mask layer 12 here forms an implantation mask that enables localized ion implantation.

In this example, the implanted region 30 may form a source implant of an access transistor. Here, it is in contact with the NISO region (source plane). Alternatively, it may be spaced apart from it.

In this example, the implanted region 40 is spaced apart from the NISO region, but alternatively, it may be in contact with it.

FIG. 1I shows the result of a formation of a dielectric layer 25 such as silicon dioxide, on the sides and on the bottom of the deep trenches 3, 4.

Prior to this, the hard mask layer 12 is removed, which exposes the upper surface of the dielectric layer 13.

A dielectric layer 25 is deposited conformally over the structure. It extends continuously over the upper surface of the dielectric layer 13 and into the deep trenches 3 and 4 (on the sidewalls and the bottom surface).

Following the formation of the dielectric layer 25, the volume of the deep trenches 3, 4 is filled with a conductive material 26, such as doped polysilicon. The deep trenches 3, 4 are filled with doped polysilicon until they project above the surface of the hard mask layer 12.

The excess conductive material 26 projecting above the dielectric layer 13 is typically removed by chemical-mechanical polishing, until it reaches the dielectric layer 13 acting as a barrier layer.

Thus, a first electronic component 5 is formed in the first deep trench 3 and a second electronic component 6 is formed in the second deep trench 4.

In summary, the deep trench etching method described above has made it possible to manufacture an assembly 1 comprising at least one semiconductor substrate comprising at least one first deep trench 3 and at least one second deep trench 4 formed within the substrate 2. The first deep trench 3 forms at least one element of a first electronic component 5, the first electronic component 5 extends from the surface of the assembly 1 according to a first depth H1. The second deep trench 4 comprises at least one element of a second electronic component 6 different from the first electronic component 5. The second electronic component 6 extends from the surface of the assembly 1 with a second depth H2. The ratio between the first depth H1 and the second depth H2 is eleven-tenth or more, for example between 1.1 and 2.

The element of the first electronic component 5 may be an element of a deep trench capacitor and the element of the second electronic component 6 may be a selection transistor vertical gate of a non-volatile memory cell of the embedded Select in Trench Memory (eSTM) type. The vertical-gate selection transistor may be identical or similar to those described in documents United States Patent Application Publication Nos. 2025/185242 A1 and 2025/240953 A1 (both of which are incorporated herein by reference).

The “eSTM” non-volatile memory cells typically include a state transistor including a control gate and a floating gate, capable of storing a charge in the floating gate representative of a binary data item, in series with a selection transistor, also called a selector or access transistor or buried transistor.

A matrix organization (called memory plane) of word lines connected to the vertical gates of the selection transistors, of control gate lines connected to the control gates, of bit lines connected to the drains of the state transistors, and of source lines or plane(s) connected to the sources of the selection transistors; makes it possible to decode the read, erase and programming access of the memory cells in the memory plane.

Before or after forming the deep trenches 3, 4, a NISO-1 region and a NISO-2 region are implanted in depth in the semiconductor substrate 2. The NISO-1 deep-implanted region, of a dopant type opposite to the dopant type of substrate 2, may offer the function of conduction regions (sources) of memory cell selection transistors, belonging to a common “source plane”.

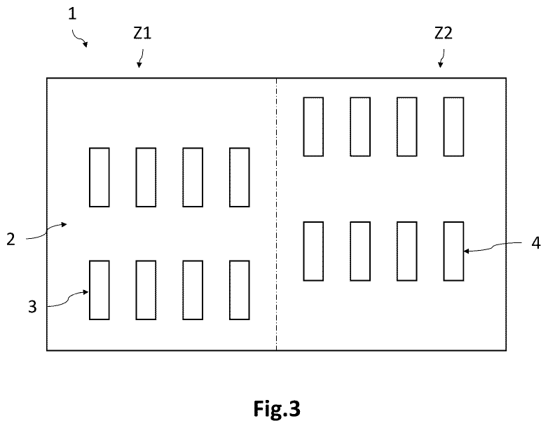

FIG. 3 shows a top view of the substrate 2 after forming the deep trenches 3, 4. The trenches 3, 4 located in the zones Z1, Z2 respectively, can be formed at positions located in different vertical planes. In other words, the trenches 3, 4 may be non-aligned, that is to say offset with respect to one another.

The manufacturing method may comprise steps for completing the vertical-gate selection transistor(s) and the deep trench capacitor(s).

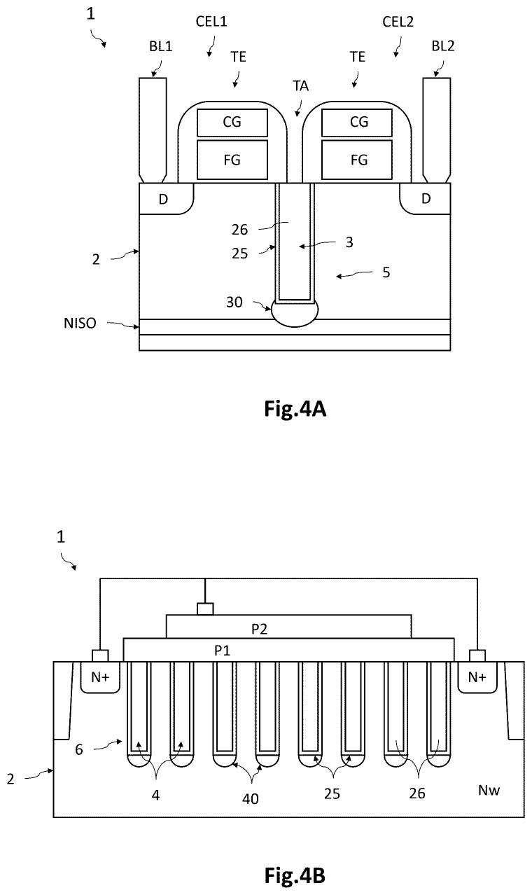

FIG. 4A is a schematic and partial cross-sectional view of two memory cells CEL1, CEL2 according to one embodiment.

Each memory cell CEL1, CEL2 comprises a state transistor TE, which enables storing a charge representative of a binary datum in its floating gate FG, and an access transistor TA, which enables selectively accessing the memory cell for writing and reading, for example.

To access the memory cells CEL1, CEL2, the drain region D of the state transistor TE is coupled to a bit-line BL1, BL2, while the source region 5 (source implant) of the access transistor TA is coupled to an underlying NISO region (source plane).

The vertical gate of the access transistor TA is formed by the deep trench 3, which comprises the electrically insulating layer 25 and the electrically conductive material 26.

The source region 5 extends from the bottom of the vertical gate toward the NISO source plane.

In this example, the source region 5 reaches the NISO source plane, but alternatively, it may be spaced apart from it. Various configurations are possible, as illustrated in United States Patent Publication Nos. 2025/185242 A1 and 2025/240953 A1, which are incorporated herein by reference.

FIG. 4B is a schematic and partial cross-sectional view of high-density deep trench capacitors.

A portion of the capacitors is formed by a respective deep trench 4, which comprises the electrically insulating layer 25 and the electrically conductive material 26.

The conductive materials 26 are coupled to a first-level layer P1, for example made of doped polysilicon, which forms a common upper electrode enabling collective biasing.

A layer P2 rests on layer P1 and is electrically insulated from it. This may be a layer dedicated to the non-volatile memory. It is electrically coupled to metal contacts located on doped regions, here of type N (N+ regions), which enable biasing of a buried N-well layer Nw of the substrate 2, here doped of type N.

A voltage V1 applied to layer P1 enables biasing of the deep trenches 4, and a voltage V2 applied to layer P2 enables biasing of the N-well Nw.

Obviously, other configurations are possible in terms of conductivity type, arrangements, and trench depths. The trenches 4 of the capacitors may be deeper or shallower than the trenches 3 forming the vertical gates of the transistors TA.

Thus, thanks to the method for forming deep trenches of different depths, it becomes possible to fabricate simultaneously deep trenches optimized for the memory cells on the one hand, and deeper or shallower high-density capacitor trenches on the other hand.

1. A method for manufacturing an integrated circuit, comprising:
forming a first mask that is resistant to a first etching on a surface of an assembly comprising at least one wafer of the semiconductor substrate, the first mask comprising at least one opening placed facing a location where at least one first deep trench is to be formed in said substrate, and wherein said first mask forms an obstruction facing a location where at least one second deep trench is to be formed in said substrate;
first etching said assembly using the first mask to partially form said at least one first trench;
at least partially removing the first mask and forming a second mask that is resistant to a second etching on said surface of said assembly, the second mask comprising a plurality of openings including at least one first opening placed facing a location of the partially formed first trench and at least one second opening placed facing the location where said at least one second deep trench is to be formed;
second etching said assembly using the second mask to form said at least one first trench and said at least one second deep trench in the assembly to different depths;
implanting ions, in the semiconductor substrate, at the bottom of said first and second deep trenches, forming a first implanted region and a second implanted region;
depositing a dielectric layer on the sidewalls and on the bottom of said deep trenches; and
depositing a conductive material filling said deep trenches;
thereby obtaining a vertical gate of a selection transistor of a non-volatile memory cell and a portion of a deep trench capacitor.

2. The method according to claim 1, further comprising filling the partially formed first trench with a planarizing material.

3. The method according to claim 2, wherein the planarizing material is selected from the group consisting of amorphous carbon or a spin-on carbon composition.

4. The method according to claim 1, further comprising:
removing at least one portion of the second mask from the surface of the assembly, after the second etching; and
depositing a dielectric material and a conductive material in the first and second trenches.

5. The method according to claim 4, wherein the conductive material is doped polysilicon.

6. The method according to claim 1, wherein the assembly further comprises at least one of the following elements:
a protective layer made of an oxide;
a second mask made of a silicon containing anti-reflective coating layer;
an anti-reflective coating made of a dielectric anti-reflective coating layer;
a hard mask layer made of an amorphous carbon layer;
a dielectric layer made of a silicon nitrite.

7. The method according to claim 1, comprising the following steps:
wherein the forming step comprises depositing a hard mask layer on the substrate and depositing the first mask covering the hard mask layer;
performing a preliminary localized etch of the hard mask layer, prior to the first etching, through the opening of the first mask, so that the opening extends through the hard mask layer;
then, removing the first mask (10);
then, performing said first etching, through the opening, thereby forming a partial trench in the semiconductor substrate;
then, depositing a filling material filling the partial trench;
then, forming a second mask on the hard mask layer;
performing an intermediate localized etch, through the first opening of the second mask, which extends through the hard mask layer and removes the filling material from the partial trench, and through the second opening of the second mask so that it extends through the hard mask layer;
performing said second etching, through the first opening of the second mask, thereby forming the deep trench, and through the second opening of the second mask, thereby forming the deep trench.

8. The method according to claim 1, wherein a first set of deep trench capacitors is fabricated simultaneously, the deep trenches of the first set having a same depth that is different from the depth of the deep trench forming the vertical gate of the selection transistor.

9. The method according to claim 1, wherein a second set of deep trench capacitors is fabricated simultaneously, the deep trenches of the second set having a same depth that is different from the depth of the deep trenches of the first set.

10. An integrated circuit according to the method of claim 1.

11. An integrated circuit, comprising:
at least one semiconductor substrate including at least one first trench and at least one second trench disposed within the substrate;
wherein the first trench comprises at least one element of a first electronic component, the first electronic component extending from the surface of the assembly to a first depth;
wherein the second trench comprises at least one element of a second electronic component, different from the first electronic component, the second electronic component extending from the surface of the assembly to a second depth;
wherein a ratio between the first depth and the second depth is greater than or equal to 1.1.

12. The integrated circuit according to claim 11, wherein the element of the first electronic component is a selection transistor of a non-volatile memory cell and the element of the second electronic component is an element of a deep trench capacitor.

13. The integrated circuit according to claim 11, wherein the first depth is between 330 and 1,200 nm, and the second depth is between 300 and 600 nm.

14. An integrated circuit, comprising:
a semiconductor substrate comprising a first deep trench and a second deep trench arranged within the semiconductor substrate and having different depths;
wherein the first and second deep trenches each comprise an electrically insulating layer covering sidewalls and a bottom of the first and second deep trenches, and an electrically conductive material filling said first and second deep trenches;
a first implanted region extending into the semiconductor substrate from the bottom of the first deep trench, and a second implanted region extending into the semiconductor substrate from the bottom of the second deep trench;
wherein the first deep trench forms part of an element of a first electronic component, and the second deep trench forms part of an element of a second electronic component different from the first electronic component;
wherein the elements of the first and second electronic components are selected from a vertical gate of a selection transistor of a non-volatile memory cell and a portion of a deep trench capacitor.

15. The integrated circuit according to claim 14, further comprising a first set of deep trench capacitors having deep trenches with a same depth that is different from the depth of the deep trench forming the vertical gate of the selection transistor.

16. Integrated circuit according to claim 15, further comprising a second set of deep trench capacitors having deep trenches with a same depth that is different from the depth of the deep trenches of the first set of deep trench capacitors.
